(19) United States
(12) Patent Application Publication
(10) Pub. No.: US 2024/0113497 A1
(43) Pub. Date: Apr. 4, 2024

(54) ILLUMINATION MODULE

(71) Applicant: AMS SENSORS SINGAPORE PTE. LTD., Singapore (SG)

(72) Inventors: Baiming GUO, Old Bridge, NJ (US); Qing WANG, Plainsboro, NJ (US)

(21) Appl. No.: 18/257,599

(22) PCT Filed: Dec. 8, 2021
(86) PCT No.: PCT/SG2021/050769

§ 371 Date: Jun. 15, 2023

(30) Foreign Application Priority Data
Dec. 15, 2020 (GB) 2019741.4

(51) Int. Cl. H01S 5/02255; H01S 5/02253

(52) U.S. Cl. CPC H01S 5/02255; H01S 5/02253; H01S 5/183

(57) ABSTRACT

An illumination module may include an emitter configured to emit light along an optical axis of the illumination module and an optical system located on or over the emitter. The optical system may include a curved surface where the curved surface is tilted in a first direction, such that the optical system introduces optical aberration in the first direction.

### CROSS-REFERENCE TO RELATED APPLICATIONS

The present application is a national stage entry according to 35 U.S.C. § 371 of PCT application No.: PCT/SG2021/050769 filed on Dec. 8, 2021; which claims priority to British patent application 2019741.4, filed on Dec. 15, 2020; all of which are incorporated herein by reference in their entirety and for all purposes.

### TECHNICAL FIELD

The present application relates to an illumination module for off-axis projection of an optical beam, particularly but not exclusively, to an illumination module configured to introduce an optical aberration to achieve a desired irradiance profile.

### BACKGROUND

The present disclosure relates to an illumination module for off-axis illumination of an optical beam, for example in an electronic device such as an augmented reality (AR) or virtual reality (VR) headset.

An off-axis illumination module typically comprises an off-axis diffuser, an array of vertical cavity surface emitting lasers (VCSELs) and a mount for achieving a desired optical beam profile. To achieve a flat far-field irradiance profile, typically an array of VCSELs generally includes around hundreds of emitters, and has a set of offsets between the array of emitters and any microlenses in two dimensions.

Off-axis illumination on a flat screen has an unwanted gradient in the irradiance profile of the light, and a non-uniform irradiance profile of an emitted beam on the flat screen. For example, a beam initially having an even “top hat” profile becomes uneven with lower irradiance levels at larger beam angles.

It is an aim of the present disclosure to address the above problem. It is desired to provide a discrete and compact illumination module with a more uniform irradiance profile when used for off-axis illumination.

### SUMMARY

In general, this disclosure proposes to overcome the above problem by using an illumination module with a tilted, curved surface (such as a lens or mirror) to introduce optical aberration.

Aspects and non-limiting features are outlined in the accompanying claims.

According to a first aspect of the present disclosure, there is provided an illumination module comprising: an emitter configured to emit light along an optical axis of the illumination module; and an optical system located on or over the emitter, the optical system comprising a curved surface, wherein the curved surface is tilted in a first direction, such that the optical system introduces optical aberration in the first direction.

The curved surface of the optical system, which is tilted in a first direction, intentionally introduces an optical aberration (such as a coma aberration) in the first direction. This compensates for the unwanted irradiance gradient when a beam is incident on a surface at an angle that is not normal to the surface, and pre-emptively corrects the beam irradiance profile. By intentionally introducing an optical aberration, a non-uniform beam profile is emitted from the illumination module, which then becomes more uniform when incident upon an off-axis imaging surface (due to the off-axis cos³ θ dependency of the irradiance profile of the beam on the imaging surface, where a is the angle between the beam and a normal to the imaging surface). This therefore provides a more uniform irradiance profile on the off-axis imaging surface. This provides an illumination module producing a flat far-field off-axis irradiance profile using fewer emitters and microlenses conventional methods for producing off-axis illumination.

The optical system may be configured to adjust an irradiance profile of the light to at least partially correct for an irradiance profile of the light which will be seen when the light is incident at a non-normal angle upon an imaging surface.

The optical system may be configured to introduce a coma aberration.

The curved surface may comprise a surface of a convex lens or a concave mirror. The aberration can be introduced by passing the beam through a curved and tilted lens, or reflecting the beam from a curved surface and a tilted surface, or a combination of these.

The curved surface may have a hyperbolic or parabolic shape. The curved surface may be substantially rotationally symmetric about an axis which extends from a centre of the curved surface.

The optical system may be configured to introduce significantly less optical aberration in a second direction than in the first direction, wherein the second direction is orthogonal to the first direction. The optical system may be configured to introduce substantially no optical aberration in the second direction. It will be appreciated that some aberration may be unintentionally introduced in the second direction. However, the optical system may be configured to not intentionally introduce optical aberration in the second direction. The optical aberration introduced in the second direction may be for example less than half, less than a quarter or less than one tenth of the optical aberration introduced in the first direction.

The curved surface may be not tilted in the second direction.

The curved surface may be tilted relative to the optical axis of the emitted light.

The optical system may further comprise a first tilted surface. The first tilted surface may be tilted in the first direction.

The first tilted surface and the curved surface may both comprise a material having the same refractive index.

The curved surface and the first tilted surface may comprise micro-optics that are formed on a chip comprising the emitter. The first tilted surface and the curved surface may be provided using on-chip micro-optics such as tilted planar and curved mirrors/lenses to re-direct the beam. The illumination module may be a VSCEL chip, and the micro-optics may be located on the VSCEL chip. Micro-optics may be defined as optical components having dimensions between tenths of a micron to hundredths of a micron. For example, the maximum size of a micro-optics component may be 100 μm.

The curved surface may be located on or over the first tilted surface. The first tilted surface may comprise an optical wedge, and the curved surface may be located directly on the first tilted surface.

Alternatively, the curved surface may comprise a lens and the illumination module may comprise at least two tilted surfaces each comprising a reflecting surface. At least one tilted surface and the curved surface may be laterally spaced from each other on a surface of the chip.

Alternatively, the first tilted surface and the curved surface may each comprise a reflecting surface, and the first tilted surface and the curved surface may be laterally spaced from each other on a surface of the chip.

The illumination module may further comprise a second tilted surface.

The emitter and the optical system may be supported by the second tilted surface.

The second tilted surface may comprise a wedge shaped substrate. Alternatively, the second tilted surface may comprise a flexible mount for attaching the illumination module to a curved structure. Alternatively, the second tilted surface may comprise a sloped groove on a flat surface.

Providing the second tilted surface to produce an off-axis beam can be achieved by providing a tilted mount, such as an embossed or flexible printed circuit board (PCB).

The emitter and the optical system of the illumination module may be then formed on the tilted mount.

The curved surface may comprise a GaAs lens or a polymer lens.

At least one of the curved surface or tilted surface may be formed using one or more of etching, replicating, embossing, molding, imprinting, or photolithography.

Embodiments of the disclosure may provide a compact, low cost, integrated off-axis illuminator including an irradiance profile correction. The illumination module may be suitable for mounting on mobile devices and wearable technologies such as augmented reality (AR) and virtual reality (VR) headsets, and other applications that require compact off-axis illumination with substantially uniform irradiance or other required beam profiles.

According to a further aspect of the present disclosure, there is provided a system comprising an illumination module as described above, and an imaging surface for receiving light from the illumination module, wherein the optical system of the illumination module is tilted relative to the imaging surface such that light from the illumination module is incident at a non-normal angle upon the imaging surface.

According to a further aspect of the present disclosure there is provided an electronic device comprising the illumination module of any preceding claim. The electronic device may be AR or VR headset or glasses. The imaging surface may be provided by the lens of the AR or VR glasses, and the illumination module may be mounted on the frame of the AR or VR glasses, for example, the illumination module may be mounted on the bridge or arms of the glasses.

Features of different aspects of the disclosure may be combined together.

Embodiments of this disclosure advantageously provide improved off-axis illumination.

The illumination module disclosed herein utilises a novel approach at least in that a curved surface is provided that is tilted in a first direction, such that an optical aberration is introduced in the first direction.

### BRIEF DESCRIPTION OF THE DRAWINGS

Some embodiments of the disclosure will now be described, by way of example only and with reference to the accompanying drawings, in which:

FIG. 1(a) illustrates schematically an off-axis illumination device;

FIG. 1(b) illustrates a schematic cross-section of an optical system having an optical wedge and a curved lens, according to an embodiment of the disclosure;

FIGS. 2(a) and 2(b) illustrate the off-axis irradiance beam profile produced by an illumination module of the disclosure;

FIG. 3 illustrates an illumination module according to an embodiment of the present disclosure, in which the illumination module includes an emitter on a flexible substrate;

FIG. 4 illustrates an alternative illumination module according to a further embodiment of the present disclosure, in which the illumination module includes an emitter on a wedge shape substrate;

FIG. 5 illustrates an alternative illumination module according to a further embodiment of the present disclosure, in which the illumination module includes an emitter on an etched or embossed substrate;

FIG. 6 illustrates an alternative illumination module according to a further embodiment of the present disclosure, in which the illumination module includes both a tilted mirror and a tilted and curved mirror located on a VSCEL chip;

FIG. 7 illustrates an alternative illumination module according to a further embodiment of the present disclosure, in which the illumination module also includes both a tilted mirror and a tilted and curved mirror located on a VSCEL chip;

FIG. 8 illustrates an alternative illumination module according to a further embodiment of the present disclosure, in which the illumination module includes a tilted mirror and a tilted lens located on a VSCEL chip; and

FIG. 9 illustrates an alternative illumination module according to a further embodiment of the present disclosure, in which the illumination module includes a tilted lens having a high refractive index, located on a VSCEL chip.

### DETAILED DESCRIPTION

Generally speaking, the disclosure provides an illumination module including an optical system having a curved surface that is tilted in a first direction, so that the optical system introduces an optical aberration in the first direction.

Some examples of the solution are given in the accompanying Figures.

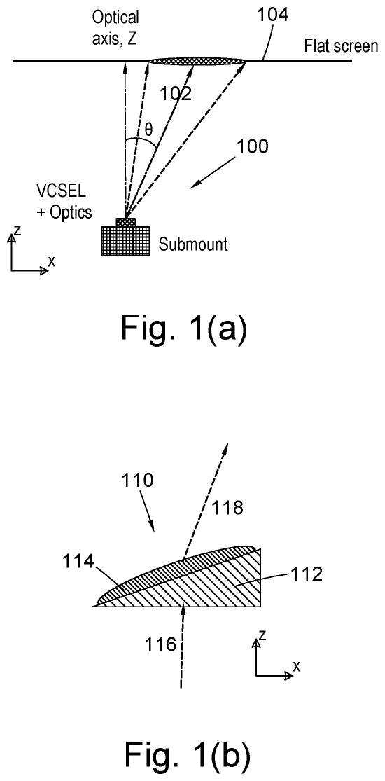

FIG. 1(a) illustrates schematically an off-axis illumination device 100 according to an embodiment of the disclosure. The illumination device 100 includes an emitter, such as a vertical cavity surface emitting laser (VSCEL), and an optical system (depicted in subsequent figures). The illumination device is configured such that the chief ray (CR) 102 from the illumination device is incident on a flat screen 104 at an offset angle of θ with respect to an optical axis Z between the illumination module and the flat screen, where the optical axis Z is normal to the flat screen. The chief ray corresponds to a ray at the centre of the beam and a middle point of the illumination produced by the illumination device. Cartesian coordinates are used in FIG. 1(a) and other figures to facilitate description. These should not be understood as requiring that the illumination device 100 has a particular orientation.

FIG. 1(b) illustrates a schematic cross-section of an optical system 110 having an optical wedge 112 and a curved lens 114, according to an embodiment of the disclosure. The optical system 110 of FIG. 1(b) is an example of an optical system that could be used in the illumination module of FIG. 1(a). In this example, the optical system 110 could be arranged over an emitter of the illumination module such that light emitted from the emitter 116 is incident on a lower surface of the optical wedge 112. The optical wedge 112 is tilted in a first direction (rotated about an axis which extends in the y-direction). The optical wedge 112 is tilted relative to the optical axis of the light emitted from the emitter 116 (i.e. subtends a non-perpendicular angle with respect to the optical axis of the light emitted from the emitter). The optical wedge 112 will be tilted relative to the flat screen (when a flat screen is present). The curved lens 114 is arranged on an upper surface of the optical wedge 112. Light from the emitter 116 incident on the optical wedge 112 passes through the optical wedge 112 and the curved lens 114. The optical wedge 112 causes the chief ray of light from the emitter 116 to bend through an angle. The titled curved lens 114 introduces an optical aberration in the first direction (the x-direction). Consequently, the light emitted by the illumination module 118 is bent away from the optical axis of the emitter and has an optical aberration. No optical aberration (or substantially no aberration) is introduced by the optical system 110 in the second direction (the y-direction) to the light emitted by the illumination module 118. Similarly, no bend of the chief ray is applied in the second direction.

The optical wedge 112 and the curved lens 114 may be separate components made from the same material. They may have the same refractive index as each other. Alternatively, the optical wedge 112 and the curved lens 114 may be formed as a single integrated component.

In this embodiment, and in other embodiments, the curved lens 114 may be a parabolic or hyperbolic convex lens. The lens 114 may be rotationally symmetric about an axis normal to the top surface of the optical wedge 112. Asymmetry is introduced into the optical system by providing the lens 114 on the optical wedge 112.

In one example, the lens 114 may have a radius of curvature of −15 μm and a diameter of −20 μm. The angle that the upper surface of the optical wedge 112 subtends with respect to the optical axis of the light emitted from the emitter may be between 5° and 7°.

An illumination device may include several emitters, for example a VSCEL array. A tilted lens may be located over each emitter of the illumination device. Tilted lenses may be provided as a microlens array. The microlens array may include optical wedges.

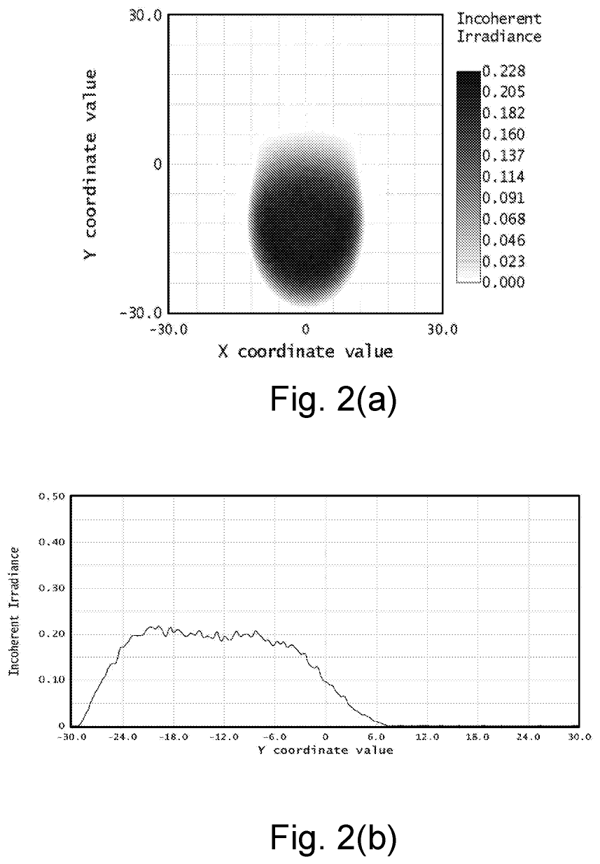

FIGS. 2(a) and 2(b) illustrate simulations of the off-axis irradiance beam profile produced by an illumination module of the disclosure, such as the illumination module of FIG. 1. The simulation was run for a detector at a designed location from a flat screen (for example, 15 mm away) and diameter (e.g., 25 mm in diameter), with an optical axis passing through the center of the 60×60 mm flat screen. In this simulation, the lens had a radius of curvature of 15 μm and was tilted at an angle of 5° relative to the flat screen. As can be seen in FIG. 2, the irradiance profile is generally top-hat shaped and substantially constant over the illuminated area.

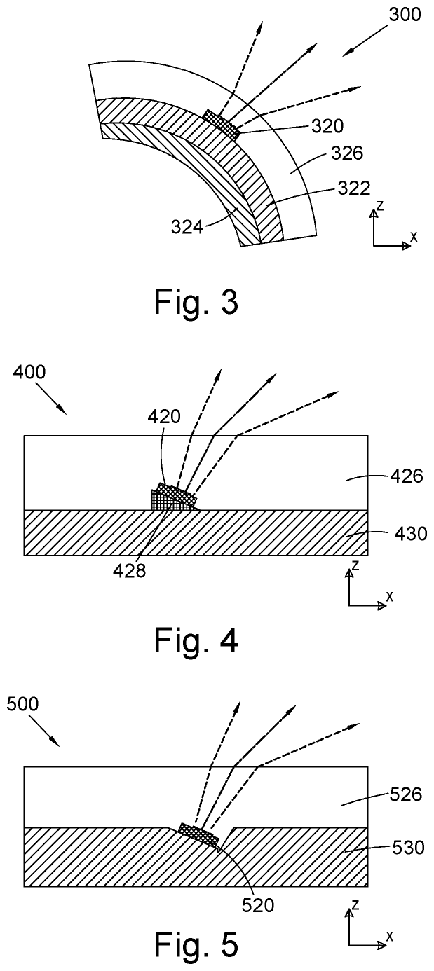

FIG. 3 illustrates an illumination module 300 according to an embodiment of the present disclosure, in which the illumination module includes an emitter 320 on a flexible substrate 322. In this embodiment, the VSCEL 320 is located on the tilted surface of a flexible substrate 322 such as a flexible printed circuit board (PCB) which is located on a chassis 324. The chassis 324 defines the offset angle θ of the CR from the VSCEL 320. An optical system including a curved microlens, tilted in a first direction such as that shown in FIG. 1(b), is located over the VSCEL 320 such that the VSCEL 320 and an optical system including the microlens are both located on the tilted surface of the flexible substrate 322. The optical system introduces an optical aberration to the light emitted from the illumination module. The VSCEL 320 and the microlens are both encapsulated in an encapsulation layer 326 located over the PCB 322.

In this embodiment, and in the embodiments shown in FIGS. 4 and 5, the offset angle of the CR is provided by locating the emitter and the optical system (such as the optical system of FIG. 1(b)) on a tilted surface (the PCB) such that light emitted from the emitter is offset. The tilted surface, that provides the offset angle, is tilted in the same direction as the curved lens in the optical system; however the tilted surface providing the offset angle may be tilted at a different angle to the curved surface.

FIG. 4 illustrates an alternative illumination module according to a further embodiment of the present disclosure, in which the illumination module 400 includes an emitter 420 on a wedge shape substrate 428. In this embodiment, the wedge-shape substrate 428 provides the tilted surface such that light emitted from the VSCEL 420 is offset. As with the embodiment of FIG. 3, an optical system including a microlens tilted in a first direction, is located over the VSCEL 420 such that the VSCEL 420 and the tilted microlens are both located on the tilted surface of the wedge shape substrate 428. The wedge-shape substrate 428 is mounted on a flat PCB 430. The wedge-shape substrate 428, the VSCEL 420 and the curved microlens are encapsulated in an encapsulation layer 426.

FIG. 5 illustrates an alternative illumination module according to a further embodiment of the present disclosure, in which the illumination module 500 includes an emitter 520 on an etched substrate 530. The etched substrate may be a PCB 530 with a sloped grove. In this embodiment, the emitter 520 is provided on a groove of an etched or embossed substrate 530 (such as a PCB) which provides the tilted surface and defines the offset angle θ. In this embodiment, the VSCEL chip 520 is connected to the PCB 530 in a flip-chip configuration.

In this embodiment, and in other embodiments, the VCSEL chip 520 can be a VCSEL array. In this case, an array of microlenses may be located over the VCSEL array, with one microlens over each individual emitter of the VCSEL array. Each microlens of the microlens array may be a tilted lens such as the lens and optical wedge of FIG. 1(b).

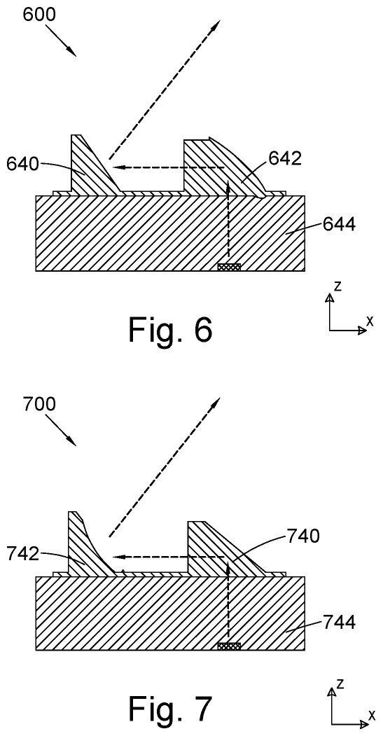

FIG. 6 illustrates an alternative illumination module 600 according to a further embodiment of the present disclosure, in which the illumination module 600 includes both a tilted mirror 640 and a tilted and curved mirror 642, located on a VSCEL chip 644 and laterally spaced apart from each other. In use, light is emitted from the VSCEL chip 644 and is incident on the tilted and curved mirror 642. The tilted, concave, curved mirror 642 produces a desired optical aberration or distortion, therefore introducing an optical aberration to the light. The light is reflected by the tilted and curved mirror 642 and travels laterally across the surface of the VSCEL chip 644 towards the tilted mirror 640, which then reflects the light to introduce the offset angle θ. Light may be emitted from the bottom surface of the VCSEL chip 644 or alternatively light be emitted from the top surface of the VCSEL chip 644. The titled mirror 640 may be tilted at an angle of less than 45 degrees (measured relative to the direction from which light is emitted by the VCSEL chip 644).

In this embodiment, and in the embodiments shown in FIGS. 7 to 9, the offset angle θ of the CR is provided by optical means. For example, the emitter emits light along an optical axis which is normal to a flat screen, and a tilted optical surface (such as a lens or a mirror) introduces an offset angle θ by reflecting or refracting the light emitted from the emitter.

The mirrors and lens of this embodiment, and the embodiments of FIGS. 7 to 9, can be moulded, replicated, and imprinted with polymers, epoxy, or other optical materials on the chip carrying the VCSEL. The same may apply for other embodiments.

The reflective surfaces of the mirrors of this embodiment, and of the embodiments of FIGS. 7 to 9, may be coated with a reflective coating, for example a metal such as gold or silver. The optical system may be encapsulated in an encapsulation layer such as that shown in FIGS. 3 to 5.

Alternatively, the reflecting surface of the mirrors of this embodiment may be internal surfaces of an optical wedge or lens and utilise total internal reflection. The optical system may be not encapsulated in an encapsulation layer, or encapsulated in an encapsulation layer having a different refractive index to the optical wedge or lens.

FIG. 7 illustrates an alternative illumination module 700 according to a further embodiment of the present disclosure, in which the illumination module also includes both a tilted mirror 740 and a tilted and curved mirror 742 located on a VSCEL chip 744. In this embodiment, the tilted mirror 740 may be a folding mirror i.e., a mirror that reflects the light emitted from the VSCEL chip 744 such that it travels laterally across the VSCEL chip 744 in a direction perpendicular to the direction of light emitted from the VSCEL chip 744, and does not introduce any optical aberration. Light reflected from the tilted mirror 740 is then incident on a tilted and asymmetrically curved mirror 742 which is tilted such that it both introduces an optical aberration and provides the offset angle θ to the light emitter from the illumination module 700.

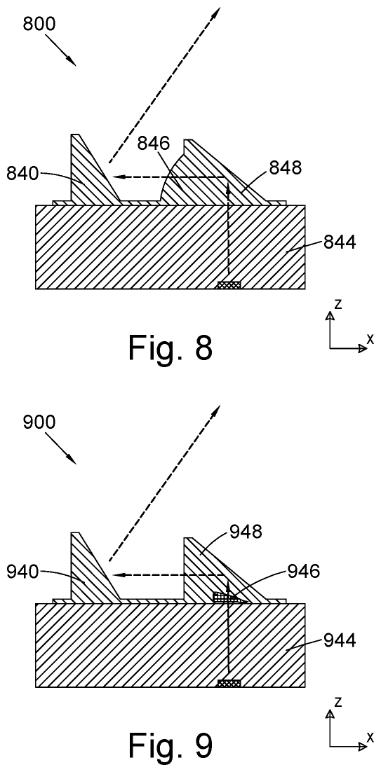

FIG. 8 illustrates an alternative illumination 800 module according to a further embodiment of the present disclosure, in which the illumination module 900 includes a tilted mirror 840 and an off-axis, tilted lens 846 located on a VSCEL chip 844. The tilted lens 846 is located adjacent to a folding mirror 848. The folding mirror 848 and the tilted lens 846 may be formed of a single component. In an illumination device including several emitters, the component comprising the tilted lens 846 and the folding mirror 848 may be one component in a larger microlens array. In use, light emitted from the VSCEL chip 844 is reflected by the folding mirror 848, and then passes through the tilted lens 846, which introduces an optical aberration to the light. The light then travels laterally across the surface of the VSCEL chip 844 towards the tilted mirror 840 which then reflects the light to introduce the offset angle θ.

FIG. 9 illustrates an alternative illumination module 900 according to a further embodiment of the present disclosure, in which the illumination module 900 includes a tilted mirror 840 and a tilted lens 946 having a relatively high refractive index, located on a VSCEL chip 944. The tilted lens 946 of this embodiment may comprise the optical wedge and curved lens of FIG. 1(b) and can be integrated on an upper surface of the VCSEL chip 944. The tilted lens 946 is formed under or within a folding mirror 948. The tilted lens 946 is formed of a material with a higher refractive index than the folding mirror 948. This allows the lens 946 to be smaller. For example, the tilted lens 946 may have a refractive index of ˜3.5 and the folding mirror 948 may have a refractive index of between 1.5 and 1.6. In use, light emitted from the VSCEL chip 944 passes through the tilted lens 946, which introduces an optical aberration to the light, and is then reflected by the folding mirror 948. The light then travels laterally across the surface of the VSCEL chip 944 towards the tilted mirror 940, which then reflects the light to introduce the offset angle θ.

Features of different embodiments may be combined with features of other embodiments.

List of reference numerals used:
100. Off-axis illumination device
102. Chief Ray
104. Flat, imaging screen
110. Optical System
112. Optical Wedge
114. Curved lens
116. Light emitted from the emitter
118. Light emitted by the illumination module
300. Illumination module
320. Emitter
322. Flexible Substrate
324. Chassis
326. Encapsulation Layer
400. Illumination module
420. Emitter
426. Encapsulation Layer
428. Wedge Shape Substrate
430. Flat PCB
500. Illumination module
520. Emitter
526. Encapsulation Layer
530. Etched PCB substrate
600. Illumination module
640. Tilted mirror
642. Tilted, curved mirror
644. VCSEL chip
700. Illumination module
740. Tilted mirror
742. Tilted, curved mirror
744. VCSEL chip
800. Illumination module
840. Tilted mirror
844. VCSEL chip
846. Tilted lens
848. Folding mirror
900. Illumination module
940. Tilted mirror
944. VCSEL chip
946. Tilted lens
948. Folding mirror

The skilled person will understand that in the preceding description and appended claims, positional terms such as ‘above’, ‘overlap’, ‘under’, ‘lateral’, etc. are made with reference to conceptual illustrations of an apparatus, such as those showing standard cross-sectional perspectives and those shown in the appended drawings. These terms are used for ease of reference but are not intended to be of limiting nature. These terms are therefore to be understood as referring to a device when in an orientation as shown in the accompanying drawings.

The skilled person will understand that the term “comprising” does not exclude other elements or steps, that the term “a” or “an” when describing a feature does not exclude a plurality of the given feature, that a single component may fulfil the functions of several means recited in the claims, and that features recited in separate dependent claims may be combined. The skilled person will also understand that any reference signs in the claims should not be construed as limiting the scope.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure, which are contemplated as falling within the scope of the appended claims. Each feature disclosed or illustrated in the present specification may be incorporated in the disclosure, whether alone or in any appropriate combination with any other feature disclosed or illustrated herein.

1. An illumination module comprising:
an emitter configured to emit light along an optical axis of the illumination module; and
an optical system located on or over the emitter, the optical system comprising a component having a curved surface, wherein the curved surface is tilted in a first direction relative to the optical axis of the emitted light, and the curved surface introduces a coma aberration in the first direction to the light emitted from the illumination module.

2. (canceled)

3. (canceled)

4. The illumination module according to claim 1, wherein the component is a concave mirror comprising the curved surface and the concave mirror is configured to reflect light from the curved surface.

5. The illumination module according to claim 1, wherein the curved surface has a hyperbolic or parabolic shape.

6. The illumination module according to claim 1, wherein the curved surface is not tilted in a second direction relative to the optical axis of the emitted light and the curved surface introduces substantially no optical aberration in the second direction.

7. (canceled)

8. (canceled)

9. The illumination module according to claim 1, wherein the optical system further comprises a first tilted surface, wherein the first tilted surface is tilted in the first direction.

10. The illumination module according to claim 9, wherein the material forming the first tilted surface and the material forming the curved surface comprise or are formed of a material having the same refractive index.

11. The illumination module according to claim 9, wherein the optical system comprises micro-optics that are formed on a chip comprising the emitter, wherein the micro-optics comprise the curved surface and the first tilted surface.

12. (canceled)

13. The illumination module according to claim 9, wherein the optical system comprises an optical wedge comprising the first tilted surface, and wherein the component having the curved surface located directly on the optical wedge.

14. The illumination module according to claim 11, wherein the optical system comprises a lens having the curved surface and at least two optical wedges having tilted surfaces each comprising a reflecting surface, and wherein at least one tilted surface and the curved surface are laterally spaced from each other on a surface of the chip.

15. The illumination module according to claim 11, wherein the first tilted surface and the curved surface each comprise a reflecting surface, and wherein the tilted surface and the curved surface are laterally spaced from each other on a surface of the chip.

16. The illumination module according to claim 1, wherein the illumination module further comprises a portion having a second tilted surface.

17. The illumination module according to claim 16, wherein the emitter and the optical system are supported by the second tilted surface.

18. The illumination module according to claim 17, wherein the illumination module comprises a wedge shaped substrate, wherein the wedge shaped substrate comprises the second tilted surface.

19. The illumination module according to claim 17, wherein the second tilted surface comprises a flexible mount for attaching the illumination module to a curved structure.

20. The illumination module according to claim 17, wherein the second tilted surface comprises a sloped groove on a flat surface.

21. The illumination module according to claim 1, wherein the curved surface comprises or is formed by a GaAs lens or a polymer lens.

22. The illumination module according to claim 9, wherein at least one of the curved surface or the first tilted surface is formed using one or more of etching, replicating, embossing, molding, imprinting, or photolithography.

23. A system comprising the illumination module of claim 1, and an imaging surface for receiving light from the illumination module,
wherein the optical system of the illumination module is tilted relative to the imaging surface such that light from the illumination module is incident at a non-normal angle upon the imaging surface.

24. An electronic device comprising the illumination module of claim 1.

25. The illumination module according to claim 1, wherein the component is a convex lens comprising the curved surface and the convex lens is configured to emit light from the curved surface.
